(19) United States
(12) Patent Application Publication
(10) Pub. No.: US 2014/0268521 A1
(43) Pub. Date: Sep. 18, 2014

(54) ELECTRONIC DEVICE

(71) Applicant: FUJITSU LIMITED, Kawasaki-shi (JP)

(72) Inventors: Hiroyuki Kawai, Kawasaki (JP); Toru Kurihara, Kawasaki (JP); Takahisa Nishi, Honjyo (JP)

(73) Assignee: FUJITSU LIMITED, Kawasaki-shi (JP)

(21) Appl. No.: 14/206,754

(22) Filed: Mar. 12, 2014

(30) Foreign Application Priority Data
Mar. 18, 2013 (JP) 2013-055349

(51) Int. Cl. H05K 5/02

(52) U.S. Cl. CPC H05K 5/0217
USPC 361/679.01

(57) ABSTRACT

An electronic device includes: a first case that includes a first inner surface; a second case that includes a second inner surface that are opposed to the first inner surface; and a packing member that includes a packing portion formed along an entire inner circumference of the first inner surface and sandwiched and compressed between the first inner surface and the second inner surface, and a projection portion projected out from the packing portion, the packing portion includes a first part provided in an area closer to the projection portion than a second part, and the second part formed thicker in a direction perpendicular to a circumferential direction of the packing portion than the first part.

### CROSS-REFERENCE TO RELATED APPLICATION

This application is based upon and claims the benefit of priority of the prior Japanese Patent Application No. 2013-055349, filed on Mar. 18, 2013, the entire contents of which are incorporated herein by reference.

### FIELD

The embodiment discussed herein is related to an electronic device.

### BACKGROUND

Hitherto, there is known a packing member that seals a housing of an electronic device. Some of this type of packing members have a resin film that is molded separately from the main body part of this packing member and is then integrated with the main body part of this packing member. These arts are disclosed, for example, in Japanese Laid-open Patent Publication No. 2010-80910.

### SUMMARY

According to an aspect of the invention, an electronic device includes: a first case that includes a first inner surface; a second case that includes a second inner surface that are opposed to the first inner surface; and a packing member that includes a packing portion formed along an entire inner circumference of the first inner surface and sandwiched and compressed between the first inner surface and the second inner surface, and a projection portion projected out from the packing portion, the packing portion includes a first part provided in an area closer to the projection portion than a second part, and the second part formed thicker in a direction perpendicular to a circumferential direction of the packing portion than the first part.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded perspective view of an electronic device;

FIG. 2 is a sectional view of the housing illustrated in FIG. 1 in an assembled state;

FIG. 3 is a fragmentary enlarged perspective view of the rear case and packing member illustrated in FIG. 1;

FIG. 4 is a sectional view of the rear case and packing member illustrated in FIG. 1;

FIG. 5 is a fragmentary enlarged perspective view illustrating a first modification of a rear case and packing member;

FIG. 6 is a sectional view of the rear case and packing member illustrated in FIG. 5; and

FIG. 7 is a sectional view illustrating a second modification of a rear case and packing member.

### DESCRIPTION OF EMBODIMENT

In the case of a packing member having a resin film such as that of the related art, the resin film has to be molded separately, and therefore the cost is increased. In addition, in the case of this packing member, the separately molded resin film has to be integrated with the main body part of the packing member. Therefore, also owing to this, the cost is increased.

In order to reduce the cost, it is conceivable to form a packing portion that is the main body part of the packing member and a fin extending from this packing portion at the same time by integral molding. However, a thin fin tends to be poorly supplied with molten material, and parts distant from a gate through which molten material is injected tend to be more poorly supplied with molten material. Therefore, the shape of the fin may vary between a part near the gate and a part distant from the gate.

An embodiment of the present disclosure will now be described with reference to the drawings.

As illustrated in FIG. 1, an electronic device 10 according to this embodiment is, for example, a mobile terminal. The electronic device 10 includes a display unit 12, a circuit board 14, a housing 16, and a packing member 18.

The housing 16 is divided in the thickness direction thereof into a rear case 20 and a front case 22 that are made of resin. The rear case 20 and the front case 22 are both formed in a quadrilateral shape in plan view. The rear case 20 is an example of a first case, and the front case 22 is an example of a second case.

The front case 22 has a front surface portion 26 facing a rear surface portion 24 of the rear case 20. The display unit 12 is attached to the front surface portion 26. The front case 22 and the rear case 20 are attached to each other. The circuit board 14, which controls the display unit 12, and so forth are housed inside the front case 22 and the rear case 20.

A looped peripheral wall portion 28 protruding toward the front case 22 is formed on the peripheral edge of the rear surface portion 24, and a peripheral wall portion 30 protruding toward the rear case 20 is formed on the peripheral edge of the front surface portion 26. The peripheral wall portion 28 and the peripheral wall portion 30 are each formed in a looped shape along the periphery of the housing 16, and are joined to each other with the packing member 18 described later therebetween as illustrated in FIG. 2.

The inner peripheral part of the peripheral wall portion 28 of the rear case 20 is formed as a facing portion 32, and the outer peripheral part of the peripheral wall portion 28 is formed as a joining portion 34. When the height direction of the peripheral wall portion 28 is defined as the direction in which the peripheral wall portion 28 protrudes from the rear surface portion 24, the facing portion 32 is formed lower than the joining portion 34.

The inner peripheral part of the peripheral wall portion 30 of the front case 22 is formed as a faced portion 36, and the outer peripheral part of the peripheral wall portion 30 is formed as a joined portion 38. When the height direction of the peripheral wall portion 30 is defined as the direction in which the peripheral wall portion 30 protrudes from the front surface portion 26, the faced portion 36 is formed lower than the joined portion 38. When the rear case 20 and the front case 22 are attached to each other, the faced portion 36 faces the facing portion 32 in the thickness direction of the housing 16, and the joined portion 38 faces the joining portion 34 in the thickness direction of the housing 16. The space between the joining portion 34 and the joined portion 38 is narrower than the space between the facing portion 32 and the faced portion 36.

The packing member 18 is formed of an elastic material (for example, rubber) softer than the rear case 20 and the front case 22. The packing member 18 is integrated with the rear case 20 by integral molding (for example, two-color molding). The packing member 18 has a packing portion 40 (see FIG. 3 and FIG. 4, too). The packing portion 40 extends along the peripheral wall portion 28 of the rear case 20 (the outer periphery of the housing 16) and is formed in a looped shape (see FIG. 1, too). The packing portion 40 is located on the facing portion 32, and is formed such that the thickness direction of the housing 16 is the height direction of the packing portion 40.

As illustrated in FIG. 3, a plurality of gate portions 42 are formed on the inner periphery of the packing portion 40. The plurality of gate portions 42 are formed by gates of a mold apparatus at the time of molding the packing member 18, and are formed like ribs extending in the height direction of the packing portion 40. The plurality of gate portions 42 are spaced from each other in the longitudinal direction (circumferential direction) of the packing portion 40.

As illustrated in FIG. 4, a fin 44 is formed integrally with the packing portion 40. As with the packing portion 40, the fin 44 extends along the peripheral wall portion 28 of the rear case 20 (the outer periphery of the housing 16) and is formed in a looped shape (see FIG. 1, too). The fin 44 is formed such that the thickness direction thereof is the height direction of the packing portion 40, and is formed thinner than the packing portion 40. The fin 44 extends from the middle part in the height direction of the packing portion 40 toward the outer periphery of the rear case 20, and the distal end 44B of the fin 44 is located on the joining portion 34.

Since the packing member 18 is integrated with the rear case 20 by integral molding as described above, the proximal end 40A of the packing portion 40 is fixed to the facing portion 32, and the distal end 44B of the fin 44 is fixed to the joining portion 34. As illustrated in FIG. 2, in a state where the rear case 20 and the front case 22 are attached to each other, the packing portion 40 is interposed in a compressed state between the facing portion 32 and the faced portion 36, and the fin 44 is interposed in a compressed state between the joining portion 34 and the joined portion 38.

As illustrated in FIG. 4, a thick portion 46 is formed on the proximal end 40A side part of the packing portion 40. The thick portion 46 is formed by protruding the proximal end 40A side part of the packing portion 40 to the inner peripheral side of the packing portion 40.

A thickening portion 48 is formed on the side of the packing portion 40 opposite to the thick portion 46. The thickening portion 48 is formed by protruding a part of the packing portion 40 closer to the proximal end 40A than the fin 44 to the distal end 44B side of the fin 44 (the outer peripheral side of the packing portion 40). The thickening portion 48 connects the proximal end 44A of the fin 44 and the part of the packing portion 40 closer to the proximal end 40A than the fin 44. The thickening portion 48 is formed over the entire circumference of the packing portion 40.

Next, the operation and effects of this embodiment will be described.

As described above in detail, according to this embodiment, the packing member 18 has a looped packing portion 40 extending along the outer periphery of the housing 16. As illustrated in FIG. 2, the packing portion 40 is interposed between the facing portion 32 formed on the peripheral wall portion 28 of the rear case 20 and the faced portion 36 formed on the peripheral wall portion 30 of the front case 22. Therefore, owing to the packing portion 40, the sealing performance (waterproof performance and dustproof performance) between the facing portion 32 and the faced portion 36 may be ensured.

The packing member 18 further has a fin 44 that is formed thinner than the packing portion 40 and that extends from the packing portion 40. The fin 44 is interposed between the joining portion 34 formed on the peripheral wall portion 28 of the rear case 20 and the joined portion 38 formed on the peripheral wall portion 30 of the front case 22. Therefore, for example, if the housing 16 is twisted, the interference between the joining portion 34 and the joined portion 38 may be suppressed by the fin 44. The generation of noise such as squeaking noise may thereby be suppressed.

The packing member 18 further has a thickening portion 48 that connects the packing portion 40 and the proximal end 44A of the fin 44, and the cross-sectional area of the proximal end 44A of the fin 44 is substantially enlarged by the thickening portion 48. Therefore, at the time of molding the packing member 18, molten material injected through gates may be supplied over the entire circumference of the thin fin 44. The shape of the fin 44 may thereby be made uniform over the entire circumference of the fin 44. Therefore, if the housing 16 is twisted, the interference between the joining portion 34 and the joined portion 38 may be suppressed more effectively.

The fin 44 extends from the middle part in the height direction of the packing portion 40, and the thickening portion 48 connects the proximal end 44A of the fin 44 and a part of the packing portion 40 closer to the proximal end 40A than the fin 44. Therefore, the cross-sectional area of a part of the packing portion 40 closer to the distal end 40B than the fin 44 is not enlarged by the thickening portion 48, and therefore the increase in the stiffness of the part of the packing portion 40 closer to the distal end 40B than the fin 44 may be suppressed. Therefore, in a state where the packing portion 40 is interposed between the facing portion 32 of the rear case 20 and the faced portion 36 of the front case 22, the part of the packing portion 40 closer to the distal end 40B than the fin 44 may be effectively compressed and deformed. As a result, the sealing performance between the facing portion 32 and the faced portion 36 may be improved.

The thickening portion 48 is formed by protruding the part of the packing portion 40 closer to the proximal end 40A than the fin 44 to the distal end 44B side of the fin 44. The thickness of the proximal end 40A side part of the packing portion 40 is thereby increased, and therefore the stiffness of the proximal end 40A side part of the packing portion 40 may be improved.

As illustrated in FIG. 3, a corner 28A of the peripheral wall portion 28 of the rear case 20 is located in the middle part between two of the plurality of gate portions 42 that are adjacent to each other in the circumferential direction (longitudinal direction) of the packing portion 40. This corner 28A tends to be poorly supplied with molten material as compared to straight parts 28B of the peripheral wall portion 28. However, the above-described thickening portion 48 (see FIG. 2 and FIG. 4) is formed over the entire circumference of the packing portion 40 including this corner 28A. Therefore, molten material may be supplied to the fin 44 at the corner 28A. Thereby, at this corner 28A, the insufficiency of the extending length of the fin 44 from the packing portion 40 may be suppressed.

Next, modifications of this embodiment will be described.

In the above-described embodiment, the thickening portion 48 is formed over the entire circumference of the packing portion 40. However, the thickening portion 48 may be formed on a part of the packing portion 40 in the circumferential direction so as to be located at least in the middle part between the plurality of gate portions 42.

For example, in a modification illustrated in FIG. 5 and FIG. 6, the thickening portion 48 is a plurality of ribs located in the middle part between the plurality of gate portions 42 and extending in the height direction of the packing portion 40. As illustrated in FIG. 6, the rib-like thickening portion 48 is formed by protruding a part of the packing portion 40 closer to the distal end 40B than the fin 44 to the distal end 44B side of the fin 44 (the outer peripheral side of the packing portion 40). The rib-like thickening portion 48 connects the proximal end 44A of the fin 44 and the part of the packing portion 40 closer to the distal end 40B than the fin 44.

When the thickening portion 48 is configured in this way, the cross-sectional area of the proximal end 44A of the fin 44 is also substantially enlarged by the rib-like thickening portion 48 in the middle part between the plurality of gate portions 42. Therefore, at the time of molding the packing member 18, molten material injected through the plurality of gates may be supplied to the middle part between the plurality of gates. The shape of the fin 44 may thereby be made uniform regardless of the distance from the gate.

When the thickening portion 48 is a plurality of ribs extending in the height direction of the packing portion 40, the material used for making the packing member 18 may be reduced as compared to the case where the thickening portion 48 is formed over the entire circumference of the packing portion 40. Thereby, the packing member 18 may be reduced in size, and the cost may be reduced.

In the modification illustrated in FIG. 5 and FIG. 6, the thickening portion 48 is a plurality of ribs extending in the height direction of the packing portion 40. However, the thickening portion 48 may have a shape other than that of the ribs extending in the height direction of the packing portion 40 as long as it is located in the middle part between the plurality of gate portions 42.

In the modification illustrated in FIG. 5 and FIG. 6, the rib-like thickening portion 48 is formed by protruding the part of the packing portion 40 closer to the distal end 40B than the fin 44 to the distal end 44B side of the fin 44. However, the rib-like thickening portion 48 may be formed by protruding a part of the packing portion 40 closer to the proximal end 40A than the fin 44 to the distal end 44B side of the fin 44.

When a corner 28A of the peripheral wall portion 28 of the rear case 20 is located in the middle part between two of the plurality of gate portions 42, the rib-like thickening portion 48 may be located at this corner 28A.

In the above-described embodiment, the thickening portion 48 is formed by protruding the part of the packing portion 40 closer to the proximal end 40A than the fin 44 to the distal end 44B side of the fin 44. However, as illustrated in FIG. 7, the thickening portion 48 may be formed only on the fin 44 side part of the packing portion 40 in the height direction.

As illustrated in FIG. 7, the thickening portion 48 may be formed so as to become gradually thinner toward the distal end 44B of the fin 44. When the thickening portion 48 is configured in this way, at the time of molding the packing member 18, molten resin may be supplied to the distal end 44B of the fin 44 more smoothly.

Such a thickening portion 48 that becomes gradually thinner toward the distal end 44B of the fin 44 may be formed on a part of the packing portion 40 closer to the distal end 40B than the fin 44.

Although, in the above-described embodiment, the packing member 18 is integrated with the rear case 20 by integral molding, the packing member 18 may be integrated with the front case 22 by integral molding. In this case, the front case 22 is an example of a first case, and the rear case 20 is an example of a second case.

Although the packing member 18 is integrated with the rear case 20 by integral molding, the packing member 18 may be molded separately from the rear case 20 and may then be attached to the rear case 20.

Although the packing portion 40 is formed in a looped shape along the outer periphery of the housing 16, the packing portion 40 does not have to have a looped shape. The fin 44 does not have to have a looped shape either, and only has to extend along the longitudinal direction of the packing portion 40.

Although the electronic device 10 is, for example, a mobile terminal, the electronic device 10 may be any electronic device other than a mobile terminal.

The above-described modifications may be appropriately implemented in combination if possible.

Although the embodiment of the present disclosure has been described, the present disclosure is not limited to the above-described embodiment. It goes without saying that various changes may be made without departing from the spirit of the present disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic device comprising:
a first case that includes a first inner surface;
a second case that includes a second inner surface that are opposed to the first inner surface; and
a packing member that includes
a packing portion formed along an entire inner circumference of the first inner surface and sandwiched and compressed between the first inner surface and the second inner surface, and
a projection portion projected out from the packing portion,
the packing portion includes
a first part provided in an area closer to the projection portion than a second part, and
the second part formed thicker in a direction perpendicular to a circumferential direction of the packing portion than the first part.

2. The electronic device according to claim 1, wherein the packing member is integrally formed with the first inner surface.

3. The electronic device according to claim 1, wherein the packing portion includes a fin that extended from the packing portion to an outside of the circumferential direction,
wherein the first part and the second part are provided in the fin.

4. The electronic device according to claim 1, wherein the fin extends from about a middle part in the height direction of the packing portion.

5. The electronic device according to claim 1, wherein the packing portion and the fin are formed in a looped shape along the outer periphery of the first inner surface.

6. The electronic device according to claim 1, wherein the second part is a rib that is located at about a middle part between the plurality of the projection portions.

7. The electronic device according to claim 1, wherein the second part is formed so as to become gradually thinner toward the distal end of the fin.

8. The electronic device according to claim 1, wherein a corner of the first case is located about a middle part between two of the plurality of the projection portions that are adjacent to each other in the longitudinal direction of the packing portion, and
the second part is located at least at the corner.

9. The electronic device according to claim 1, wherein the second part protrudes from a connection point between the packing portion and the fin.

10. The electronic device according to claim 1, wherein the second part is only intermittently formed along the packing member so as to comprise a plurality of ribs.

11. The electronic device according to claim 10, wherein each of the plurality of projection portions is formed at an interval of a plurality of intervals between adjacent ribs of the plurality of ribs.
